(19) United States
(12) Patent Application Publication
(10) Pub. No.: US 2023/0020001 A1
(43) Pub. Date: Jan. 19, 2023

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventor: Atsushi HIRANO, Toyama-shi (JP)

(73) Assignee: Kokusai Electric Corporation, Tokyo (JP)

(21) Appl. No.: 17/945,764

(22) Filed: Sep. 15, 2022

Related U.S. Application Data
(63) Continuation of application No. PCT/JP2021/006936, filed on Feb. 24, 2021.

(30) Foreign Application Priority Data
Mar. 17, 2020 (JP) 2020-047037

(51) Int. Cl. C23C 16/44; C23C 16/455; C23C 16/52; H01L 21/02

(52) U.S. Cl. CPC C23C 16/4408; C23C 16/45574; C23C 16/45578; C23C 16/52; H01L 21/0262; C23C 16/46

(57) ABSTRACT

The present disclosure provides a technique that includes: loading a substrate into a process chamber in which the substrate is processed; and processing the substrate by supplying a first inert gas to a peripheral portion of the substrate and simultaneously supplying a mixed gas of a second inert gas different from the first inert gas and a process gas to a surface of the substrate.

### CROSS-REFERENCE TO RELATED APPLICATION

This application is a bypass continuation application of PCT International Application No. PCT/JP2021/006936, filed on Feb. 24, 2021, in the WIPO, the international application being based upon and claiming the benefit of priority from Japanese Patent Application No. 2020-047037, filed on Mar. 17, 2020, in the Japanese Patent Office, the entire contents of which are hereby incorporated by reference.

### BACKGROUND

### Field

The present disclosure relates to a substrate processing apparatus, a method of manufacturing a semiconductor device, and a recording medium.

### Related Art

In related art, processing of supplying a process gas to a substrate (wafer) in a process chamber and forming a film on the substrate is performed as one step of manufacturing a semiconductor device.

As a semiconductor device becomes finer and deeper, the supply amount of a process gas may be insufficient near the center of a wafer, and in-plane film thickness uniformity of a film formed on the wafer may deteriorate. In the known documents, in order to cope with this, a counter gas is supplied and a process gas is supplied to the center of a wafer to improve the in-plane film thickness uniformity.

### SUMMARY

According to the present disclosure, there is provided a technique (or configuration) capable of processing of a large surface area wafer possible without increasing the supply amount and the discharge amount of a gas.

According to one embodiment of the present disclosure, there is provided a technique that includes:

loading a substrate into a process chamber in which the substrate is processed; and

processing the substrate by supplying a first inert gas to a peripheral portion of the substrate and simultaneously supplying a mixed gas of a second inert gas different from the first inert gas and a process gas to a surface of the substrate.

### BRIEF DESCRIPTION OF DRAWINGS

FIG. 1 is a schematic configuration diagram of a substrate processing apparatus according to the present embodiment, and particularly illustrates a process furnace portion in a longitudinal cross section.

FIG. 2 is a cross-sectional view taken along line A-A of the process furnace illustrated in FIG. 1.

FIG. 3 is a block diagram illustrating a configuration of a controller included in the substrate processing apparatus illustrated in FIG. 1.

FIG. 4 is a diagram schematically illustrating a distribution of gases on a wafer in a case of using a second inert gas which is easily diffused.

FIG. 5 is a diagram schematically illustrating a distribution of gases on a wafer in a case of using a second inert gas which is hardly diffused.

FIG. 6 is a diagram illustrating a source gas concentration between a center and an end side of a wafer.

### DETAILED DESCRIPTION

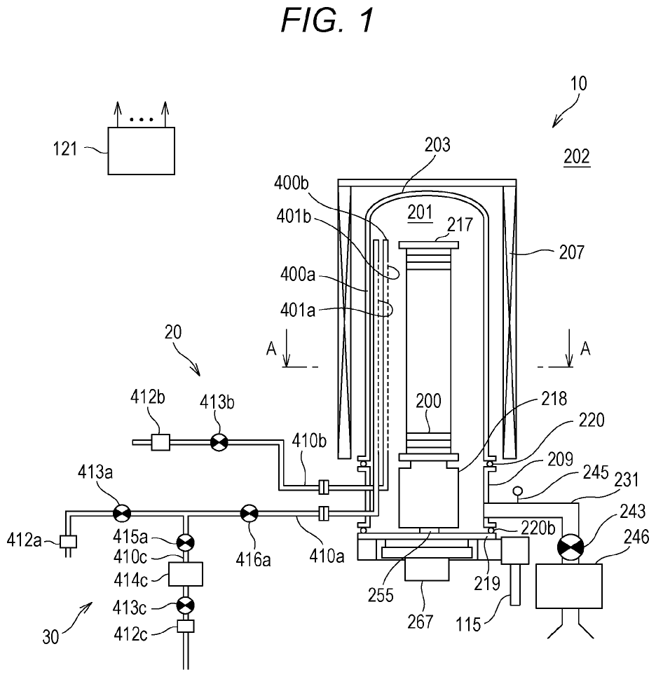

Hereinafter, one or more embodiments (also simply referred to as “embodiments”) of the present disclosure will be described with reference to FIGS. 1 to 3. Note that the drawings used in the following description are all schematic, and a dimensional relationship among elements, a ratio among elements, and the like illustrated in the drawings do not necessarily coincide with actual ones. In addition, a dimensional relationship among elements, a ratio among elements, and the like do not necessarily coincide among the plurality of drawings.

A substrate processing apparatus is configured as an example of an apparatus used in a substrate processing step which is one step of a semiconductor device manufacturing process. This substrate processing apparatus 10 includes a first inert gas supply system 20, a processing gas supply system 30, and a controller 121 serving as an example of a controller.

(Process Chamber)

A process furnace 202 includes a heater 207 serving as a heating means (heating mechanism). The heater 207 has a cylindrical shape, and is vertically installed by being supported by a heater base (not illustrated) serving as a holding plate.

Inside the heater 207, a reaction tube 203 constituting a reaction container (process container) is disposed concentrically with the heater 207. The reaction tube 203 is made of a heat resistant material (for example, quartz (SiO₂) or silicon carbide (SiC), and is formed in a cylindrical shape with an upper end closed and a lower end opened. The process chamber 201 is configured to be able to house wafers 200 serving as substrates in a state where the wafers 200 are arranged in multiple stages in a vertical direction in a horizontal posture by a boat 217, to be described later.

In the process chamber 201, nozzles 400a and 400b are disposed so as to penetrate a side wall of a manifold 209. To the nozzles 400a and 400b, gas supply pipes 410a and 410b serving as gas supply lines are connected, respectively. As described above, the reaction tube 203 includes the two types of nozzles 400a and 400b and the two gas supply pipes 410a and 410b, and is configured to be able to supply a plurality of types of gases into the process chamber 201. Here, a mixed gas of a process gas and an inert gas (hereinafter, referred to as a second inert gas) serving as a carrier gas supplied in an inert state (under a condition of not reacting) to the process gas can be supplied through the nozzle 400a, and an inert gas (hereinafter, referred to as a first inert gas) different from the second inert gas can be supplied through the nozzle 400b. That is, it is configured to be able to supply three types of gases consisting of the process gas, the first inert gas, and the second inert gas. The nozzle 400b is disposed so as to sandwich the nozzle 400a in a circumferential direction of the process chamber 201. Note that four or more types of gases may be supplied.

However, the process furnace 202 of the present embodiments are not limited to the above-described form. For example, a metal manifold supporting the reaction tube 203 may be disposed below the reaction tube 203, and each nozzle may be disposed so as to penetrate a side wall of the manifold. In this case, an exhaust pipe 231 described later may be further disposed in the manifold. Even in this case, the exhaust pipe 231 may be disposed not in the manifold but in a lower portion of the reaction tube 203. As described above, a furnace opening portion of the process furnace 202 may be made of metal, and a nozzle or the like may be attached to the metal furnace opening portion.

The nozzles 400a and 400b are configured as L-shaped long nozzles, and horizontal portions thereof are disposed so as to penetrate a side wall of the manifold 209. Vertical portions of the nozzles 400a and 400b are disposed in an annular space formed between an inner wall of the reaction tube 203 and the wafers 200 so as to rise upward (upward in a stacking direction of the wafers 200) along the inner wall of the reaction tube 203 (that is, so as to rise from one end side to the other end side of a wafer arrangement region). That is, the nozzles 400a and 400b are disposed along the wafer arrangement region in a region horizontally surrounding the wafer arrangement region on a side of the wafer arrangement region in which the wafers 200 are arranged.

For example, two vertical portions of the nozzle 400a may be disposed, and two vertical portions of the nozzle 400b may be disposed. The vertical portions may be an upstream portion and a downstream portion of a U-shaped pipe, or may be independent pipes. When the vertical portions of the nozzle 400a are independent pipes, the vertical portions are branched from and connected to the gas supply pipe 410a. Similarly, when the vertical portions of the nozzle 400b are independent pipes, the vertical portions are branched from and connected to the gas supply pipe 410b.

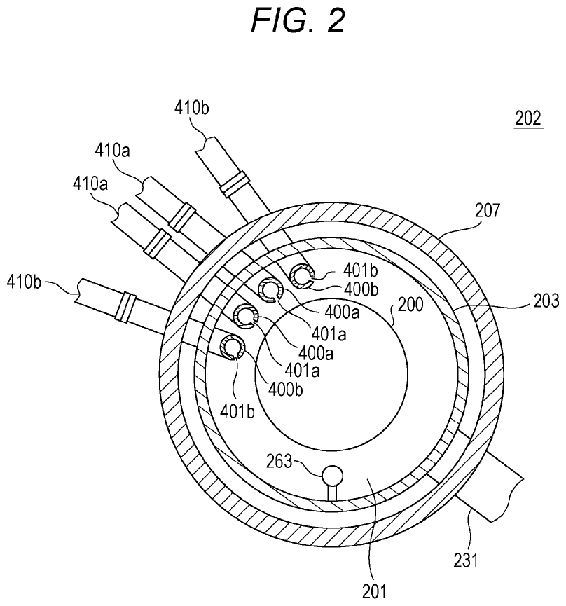

Note that one of the two nozzles 400a may be used for supplying the process gas, and the other may be used for supplying the second inert gas. One vertical portion of the nozzle 400a may be disposed. In FIG. 2, the arrangement of the nozzles 400a and 400b is symmetrical in plan view, but the arrangement does not have to be symmetrical.

On a side surface of the nozzle 400a, a gas supply hole 401a through which the mixed gas is supplied (ejected) is formed. The gas supply hole 401a is opened so as to face, for example, a central portion (a center side of the reaction tube 203) on a surface of the wafer 200 in the process chamber 201. A plurality of the gas supply holes 401a are formed from a lower portion to an upper portion of the reaction tube 203, have the same opening area, and are formed at the same opening pitch. However, the gas supply hole 401a is not limited to the above-described form. For example, the opening area may be gradually increased from a lower portion to an upper portion of the reaction tube 203. As a result, flow rates of a gas supplied through the gas supply holes 401a can be made uniform.

On a side surface of the nozzle 400b, a gas supply hole 401b through which a gas is supplied (ejected) is formed. Specifically, the gas supply hole 401b is opened so as to face a peripheral portion of the wafer 200 in the process chamber 201. A plurality of the gas supply holes 401b are formed from a lower portion to an upper portion of the reaction tube 203, have the same opening area, and are formed at the same opening pitch. However, the gas supply hole 401b is not limited to the above-described form. For example, the opening area may be gradually increased from a lower portion to an upper portion of the reaction tube 203. As a result, flow rates of a gas supplied through the gas supply holes 401b can be made uniform.

As described above, in a gas supply method in the present embodiments, a gas is transferred via the nozzles 400a and 400b disposed in an annular and longitudinally long space defined by an inner wall of the reaction tube 203 and ends of the plurality of wafers 200, that is, in a cylindrical space. Gases are ejected into the reaction tube 203 for the first time in the vicinity of the wafers 200 from the gas supply holes 401a and 401b opened in the nozzles 400a and 400b, respectively, and a main flow of a gas in the reaction tube 203 is in a direction parallel to surfaces of the wafers 200, that is, a horizontal direction. With such a configuration, it is possible to uniformly supply a gas to the wafers 200, and there is an effect that the film thicknesses of thin films formed on the wafers 200 can be made uniform. Note that a gas that has flowed on surfaces of the wafers 200, that is, a gas (residual gas) remaining after a reaction flows toward an exhaust port, that is, the exhaust pipe 231 to be described later, but the flow direction of the residual gas is appropriately specified by the position of the exhaust port and is not limited to the vertical direction.

(First Inert Gas Supply System)

The first inert gas supply system 20 is, for example, the nozzle 400b that is disposed in the process chamber 201 in which a substrate is processed and supplies the first inert gas to a peripheral portion of the wafer 200 in the process chamber 201. To the nozzle 400b, the gas supply pipe 410b or the like serving as a first inert gas supply line is connected. The gas supply pipe 410b includes, for example, a mass flow controller (MFC) 412b serving as a flow rate control device and a valve 413b which is an on-off valve in this order from an upstream side.

From the gas supply pipe 410b, for example, a nitrogen (N₂) gas is supplied as the first inert gas into the process chamber 201 via the MFC 412b, the valve 413b, and the nozzle 400b. The first inert gas supplied from the gas supply pipe 410b acts as a purge gas or a dilution gas in a substrate processing step described later.

Mainly, the gas supply pipe 410b, the MFC 412b, and the valve 413b constitute the first inert gas supply system 20. The nozzle 400b may be included in the first inert gas supply system 20. Since the first inert gas also acts as a purge gas, the first inert gas supply system 20 can also be referred to as a purge gas supply system.

(Process Gas Supply System)

The process gas supply system 30 is, for example, the nozzle 400a disposed in the process chamber 201 so as to be separated from the first inert gas supply system 20 in a circumferential direction of a substrate by a predetermined distance, and supplies a mixed gas of the process gas and the second inert gas different from the first inert gas to a surface of the wafer 200 in the process chamber 201 through the nozzle 400a. The nozzle 400a is disposed so as to be separated from the two nozzles 400b by a predetermined distance and sandwiched between the nozzles 400b in a circumferential direction of the process chamber 201.

To the nozzle 400a, a gas supply pipe 410a or the like is connected. A second inert gas supply line in the gas supply pipe 410a includes, for example, a mass flow controller (MFC) 412a serving as a flow rate control device and valves 413a and 416a which are on-off valves in this order from an upstream side.

As the second inert gas, for example, a hydrogen gas, a helium gas, a nitrogen gas (N₂), or an argon gas can be used in ascending order of a molecular weight and descending order of easy diffusion. The second inert gas may be a rare gas. For example, the second inert gas may be selected from the group consisting of a He gas, a Ne gas, an Ar gas, a Kr gas, and a Xe gas. Furthermore, the second inert gas may be selected according to the surface area of the wafer 200.

The second inert gas may be constituted by a gas having a diffusion coefficient different from that of the first inert gas. For example, the second inert gas may be constituted by a gas having a diffusion coefficient larger than that of the first inert gas.

The process gas supply system 30 may be configured to be able to select the second inert gas according to a processing condition. In addition, the process gas supply system 30 may be configured to be able to adjust the concentration of the process gas on a surface of the wafer 200 according to the type of the second inert gas.

The second inert gas can have a molecular weight different from that of the first inert gas. For example, as the second inert gas, a gas having a molecular weight smaller than that of the first inert gas may be selected.

A flow rate of the second inert gas may be set to be larger than that of the process gas. The flow rate of the second inert gas may be set to be larger than that of the process gas and that of the first inert gas.

Between the valve 413a and the valve 416a in the gas supply pipe 410a, a downstream end of a gas supply pipe 410c serving as a process gas supply line is connected. In this portion, the process gas and the second inert gas are merged. The gas supply pipe 410c includes an MFC 412c, a valve 413c serving as an on-off valve, a vaporizer 414c, and a valve 415a in this order from an upstream side.

From the gas supply pipe 410c, as a source gas (source) which is the process gas, a metal-containing gas containing a metal element is supplied into the process chamber 201 via the MFC 412c, the valve 413c, the vaporizer 414c, the valve 415a, and the nozzle 400a. The metal-containing gas is, for example, a source gas containing a metal element such as Al, Ti, Hf, Zr, Ta, Mo, or W. When a liquid source or a solid source is not used as the source gas but a source in a gaseous state under normal temperature and normal pressure is used, a vaporizing or sublimating system such as the vaporizer 414c is unnecessary.

In the present specification, in a case where the term “source” is used, the term may mean “a liquid source in a liquid state”, “a source gas in a gaseous state”, or both of these.

Mainly, the gas supply pipes 410a and 410c, the MFCs 412a and 412c, the valves 413a, 413c, 415a, and 416a, and the vaporizer 414c constitute the process gas supply system 30. The nozzle 400a may be included in the process gas supply system 30. The process gas supply system 30 can also be simply referred to as a gas supply system.

When such a metal-containing gas as described above serving as a source gas flows from the gas supply pipe 410c, mainly, the gas supply pipe 410c, the MFC 412c, the valve 413c, the vaporizer 414c, and the valve 415a constitute a metal-containing gas supply system serving as a source gas supply system. The nozzle 400a may be included in the source gas supply system.

(Exhaust System)

The reaction tube 203 includes the exhaust pipe 231 that discharges an atmosphere in the process chamber 201. To the exhaust pipe 231, a vacuum pump 246 serving as a vacuum exhaust device is connected via a pressure sensor 245 serving as a pressure detector that detects a pressure in the process chamber 201 and an auto pressure controller (APC) valve 243 serving as a pressure adjuster. The APC valve 244 can perform vacuum exhaust and vacuum exhaust stop in the process chamber 201 by opening and closing the valve in a state where the vacuum pump 246 is operated, and furthermore, can adjust a pressure in the process chamber 201 by adjusting the degree of valve opening based on pressure information detected by the pressure sensor 245 in a state where the vacuum pump 246 is operated. Mainly, the exhaust pipe 231, the APC valve 243, and the pressure sensor 245 constitute an exhaust system. The vacuum pump 246 may be included in the exhaust system.

Below the reaction tube 203, a seal cap 219 serving as a furnace opening lid capable of airtightly closing a lower end opening of the reaction tube 203 is disposed. The seal cap 219 is configured to abut against a lower end of the reaction tube 203 from a lower side in the vertical direction. The seal cap 219 is made of, for example, a metal such as SUS and is formed in a disk shape. On an upper surface of the seal cap 219, an O-ring 220 serving as a seal member abutting against the lower end of the reaction tube 203 is disposed. On a side of the seal cap 219 opposite to the process chamber 201, a rotation mechanism 267 that rotates a boat 217 described later is disposed. A rotation shaft 255 of the rotation mechanism 267 penetrates the seal cap 219 and is connected to the boat 217. The rotation mechanism 267 is configured to rotate the wafer 200 by rotating the boat 217. The seal cap 219 is configured to be raised and lowered in the vertical direction by a boat elevator 115 serving as a raising/lowering mechanism vertically disposed outside the reaction tube 203. The boat elevator 115 is configured to be able to load the boat 217 into the process chamber 201 and unload the boat 217 out of the process chamber 201 by raising and lowering the seal cap 219. That is, the boat elevator 115 is configured as a transfer device (transfer mechanism) that transfers the boat 217, that is, the wafer 200 to the inside and the outside of the process chamber 201.

The boat 217 serving as a substrate support tool is configured to support a plurality of, for example, 25 to 200 wafers 200 in multiple stages while the wafers 200 are arranged in the vertical direction in a horizontal posture and in a state where the centers thereof are aligned with each other, that is, such that the wafers 200 are arranged at intervals. The boat 217 is made of a heat resistant material such as quartz or SiC, for example. In a lower portion of the boat 217, a heat insulating plate 218 made of a heat resistant material such as quartz or SiC, for example, is supported in multiple stage in a horizontal posture. With this configuration, heat from the heater 207 is less likely to be transferred to the seal cap 219 side. However, the present embodiments are not limited to the above-described form. For example, a heat insulating tube configured as a cylindrical member made of a heat resistant material such as quartz or SiC may be disposed without disposing the heat insulating plate 218 in the lower portion of the boat 217.

In the reaction tube 203, a temperature sensor 263 serving as a temperature detector is disposed, and it is configured such that the temperature in the process chamber 201 has a desired temperature distribution by adjusting an energization amount to the heater 207 based on temperature information detected by the temperature sensor 263. The temperature sensor 263 is formed in an L shape similarly to the nozzles 400a and 400b, and is disposed along an inner wall of the reaction tube 203.

(Controller)

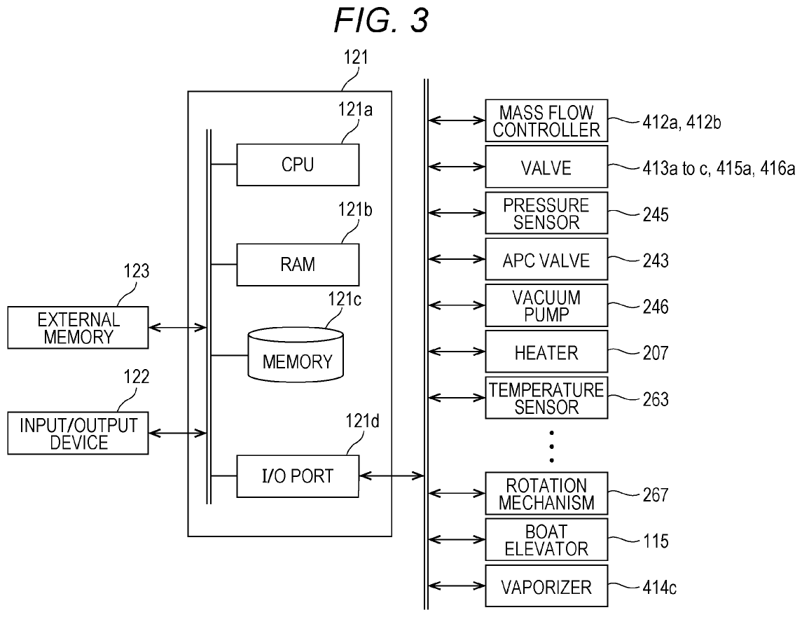

As illustrated in FIG. 3, the controller 121 is configured as a computer including a central processing unit (CPU) 121a, a random access memory (RAM) 121b, a memory 121c, and an I/O port 121d. The RAM 121b, the memory 121c, and the I/O port 121d are configured to exchange data with the CPU 121a via an internal bus. To the controller 121, an input/output device 122 configured as, for example, a touch panel is connected.

The memory 121c is constituted by, for example, a flash memory or a hard disk drive (HDD). In the memory 121c, a control program that controls an operation of the substrate processing apparatus, a process recipe in which procedures, conditions, and the like of substrate processing described later are described, and the like are readably stored. The process recipe is combined so as to cause the controller 121 to execute procedures in a substrate processing step described later to obtain a predetermined result, and functions as a program. Hereinafter, the process recipe, the control program, and the like are also collectively and simply referred to as a program. In the present specification, the term “program” may include only the process recipe alone, only the control program alone, or both of these. The RAM 121b is configured as a memory area (work area) in which a program, data, and the like read by the CPU 121a are temporarily stored.

The I/O port 121d is connected to the MFCs 412a and 412b, the valves 413a to 413c, 415a, and 416a, the vaporizer 414c, the APC valve 243, the pressure sensor 245, the vacuum pump 246, the heater 207, the temperature sensor 263, the rotation mechanism 267, the boat elevator 115, and the like described above.

The CPU 121a is configured to read the control program from the memory 121c and execute the control program, and read the process recipe from the memory 121c in response to an input of an operation command from the input/output device 122. The CPU 121a is configured to control various gases flow rate adjusting operations of the MFCs 412a and 412b, open and close operations of the valves 413a to 413c, 415a, and 416a, a vaporizing operation of the vaporizer 414c, an open and close operation of the APC valve 243, a pressure adjusting operation of the APC valve 243 based on the pressure sensor 245, a temperature adjusting operation of the heater 207 based on the temperature sensor 263, start and stop of the vacuum pump 246, a rotation and rotation speed adjusting operation of the boat 217 by the rotation mechanism 267, a raising/lowering operation of the boat 217 by the boat elevator 115, and the like in accordance with the read process recipe.

The controller 121 can be configured by installing the above-described program stored in an external memory (for example, a magnetic tape, a magnetic disk such as a flexible disk or a hard disk, an optical disk such as a CD or a DVD, a magneto-optical disk such as an MO, or a semiconductor memory such as a USB memory or a memory card) 123 in a computer. The memory 121c and the external memory 123 are configured as computer-readable recording media. Hereinafter, the computer-readable recording media are collectively and simply referred to as a recording medium. In the present specification, the term “recording medium” may include only the memory 121c alone, only the external memory 123 alone, or both of these. Note that the program may be provided to the computer by using a communication means such as the Internet or a dedicated line without using the external memory 123.

(Program)

A program according to the present embodiments are a program causing the substrate processing apparatus 10 including: the first inert gas supply system 20 that is disposed in the process chamber 201 in which the wafer 200 is processed and supplies the first inert gas to a peripheral portion of the wafer 200 in the process chamber 201; the process gas supply system that is disposed in the process chamber 201 so as to be separated from the first inert gas supply system 20 in a circumferential direction of the wafer 200 by a predetermined distance and supplies a mixed gas of the second inert gas different from the first inert gas and the process gas to a surface of the wafer 200; and the controller 121 that controls the process gas supply system and the first inert gas supply system 20 so as to process the wafer 200 by supplying the mixed gas and the first inert gas, to execute a procedure of loading the wafer 200 into the processing chamber 201 and a procedure of supplying the first inert gas to the peripheral portion of the peripheral portion of the wafer 200 in the process chamber 201 and supplying the mixed gas to the surface of the wafer 200 in the process chamber 201 to process the wafer 200, with a computer.

(2) Substrate Processing Step (Film Forming Step)

Next, the substrate processing step, which is one step of a semiconductor device manufacturing process, will be described. A method of manufacturing a semiconductor device according to the present embodiments include a step of: loading the wafer 200 serving as an example of a substrate into the process chamber 201 in which the wafer 200 is processed; and supplying the first inert gas to a peripheral portion of the wafer 200 in the process chamber 201 and supplying a mixed gas of the second inert gas different from the first inert gas and the process gas to a surfaces of the wafer 200 in the process chamber 201 to process the wafer 200.

These steps are performed using the above-described process furnace 202 of the substrate processing apparatus 10. In the following description, operations of the units constituting the substrate processing apparatus 10 are controlled by the controller 121.

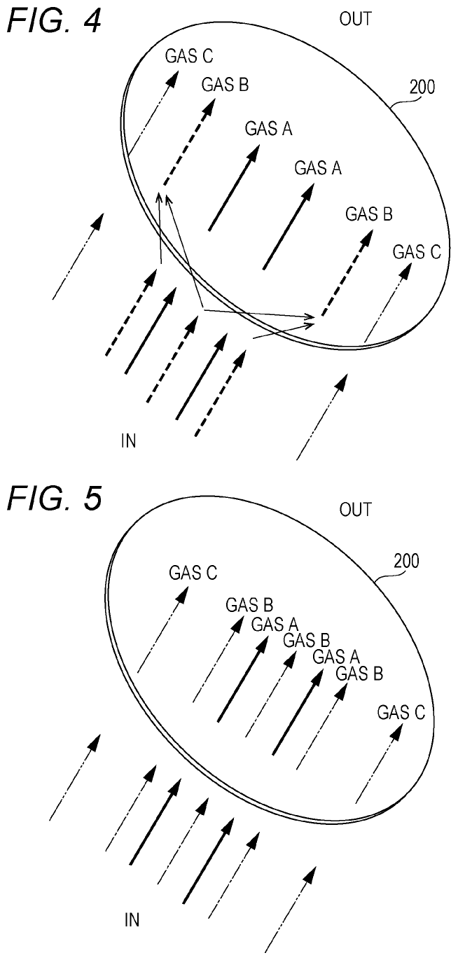

In the present specification, “perform processing (or referred to as a process, a cycle, a step, or the like) a predetermined number of times” means that this processing or the like is performed once or a plurality of times. That is, it means that the processing is performed one or more times. FIG. 4 illustrates an example in which each processing (cycle) is repeated n times to perform n cycles. A value of n is appropriately selected according to a film thickness required in a finally formed film. That is, the number of times at which each processing described above is performed is determined according to a target film thickness.

Note that in the present specification, the term “wafer” may mean “a wafer itself” or “a stack (assembly) of a wafer and a predetermined layer, film, or the like formed on a surface of the wafer” (that is, a wafer with a predetermined layer, film, or the like formed on a surface of the wafer is referred to as a wafer). In the present specification, the term “surface of a wafer” may mean “a surface (exposed surface) of a wafer itself” or “a surface of a predetermined layer, film, or the like formed on a wafer, that is, an outermost surface of a wafer serving as a stack”.

Therefore, in the present specification, the description “supply a predetermined gas to a wafer” may mean “directly supply a predetermined gas to a surface (exposed surface) of a wafer itself” or “a predetermined gas is supplied to a layer, a film, or the like formed on a wafer, that is, to an outermost surface of a wafer serving as a stack”. In the present specification, the description “form a predetermined layer (or film) on a wafer” may mean “directly form a predetermined layer (or film) on a surface (exposed surface) of a wafer itself”, or “form a predetermined layer (or film) on a layer, a film, or the like formed on a wafer, that is, on an outermost surface of a wafer serving as a stack”.

Note that the term “substrate” in the present specification is similar to the term “wafer”, and in this case, it is only required to replace “wafer” with “substrate” in the above description.

In the present specification, the term metal film means a film made of a conductive substance containing a metal atom, and examples thereof include a conductive metal nitride film, a conductive metal oxide film, a conductive metal oxynitride film, a conductive metal composite film, a conductive metal alloy film, a conductive metal silicide film, a conductive metal carbide film, and a conductive metal carbonitride film.

(Wafer Charge and Boat Load)

When the boat 217 is charged with the plurality of wafers 200 (wafer charge), as illustrated in FIG. 1, the boat 217 supporting the plurality of wafers 200 is raised and loaded into the process chamber 201 (boat load) by the boat elevator 115. In this state, the seal cap 219 is in a state of airtightly closing a lower end opening of the reaction tube 203 via the O-ring 220.

(Pressure Adjustment and Temperature Adjustment)

The vacuum pump 246 performs vacuum exhaust such that the inside of the process chamber 201, that is, a space where the wafers 200 are present, has a desired pressure (degree of vacuum). At this time, the pressure in the process chamber 201 is measured by the pressure sensor 245, and the APC valve 243 is feedback-controlled based on the measured pressure information (pressure adjustment). The vacuum pump 246 maintains a state of being constantly operated at least until the processing on the wafers 200 is completed. The inside of the process chamber 201 is heated by the heater 207 so as to have a predetermined temperature. At this time, an energization amount to the heater 207 is feedback-controlled based on temperature information detected by the temperature sensor 263 such that the inside of the process chamber 201 has a predetermined temperature distribution (temperature adjustment). The inside of the process chamber 201 is continuously heated by the heater 207 at least until processing on the wafers 200 is completed. Subsequently, rotation of the boat 217 and the wafers 200 is started by the rotation mechanism 267. The rotation of the boat 217 and the wafers 200 by the rotation mechanism 267 is continuously performed at least until processing on the wafers 200 is completed.

(Film Forming Step)

Next, in FIGS. 4 and 5, a step of supplying the first inert gas to a peripheral portion of the wafer 200 and supplying the mixed gas to a surface of the substrate to process the wafer 200 will be described. FIG. 4 is a diagram schematically illustrating a distribution of gases on the wafer 200 when the process gas (gas A), the second inert gas (gas B), and the first inert gas (gas C) are supplied.

In FIG. 4, since the second inert gas (gas B) has a small molecular weight and is easily diffused, when the mixed gas is supplied to a surface of the wafer 200, the second inert gas (gas B) in the mixed gas is diffused and mixed with the first inert gas (gas C). As a result, the concentration of the second inert gas (gas B) in the central portion of the wafer 200 decreases. On the other hand, since the process gas and the first inert gas have low diffusion speeds, the process gas (gas A) remains in the central portion of the wafer 200. Therefore, the concentration of the process gas (gas A) in the central portion of the wafer 200 can be increased. In particular, when a hydrogen gas having the smallest molecular weight is used as the second inert gas, the concentration of the process gas in the central portion of the wafer 200 can be increased.

FIG. 5 is a diagram schematically illustrating a distribution of gases on the wafer 200 when the process gas, the second inert gas, and the first inert gas are supplied.

In FIG. 5, since the second inert gas (gas B) has a large molecular weight and is hardly diffused, when the mixed gas is supplied to a surface of the wafer 200, the second inert gas (gas B) in the mixed gas is not diffused so much and remains in the central portion of the wafer 200. As described above, since the process gas (gas A) also remains in the central portion of the wafer 200, a change in the concentration of the process gas (gas A) in the central portion of the wafer 200 is small.

As described above, it is possible to increase or decrease the concentration of the process gas (gas A) in the central portion of the wafer 200 by selecting the second inert gas (gas B). Therefore, a plurality of supply pipes for the second inert gas may be disposed in the processing gas supply system 30 such that the second inert gas can be appropriately selected.

Note that since a gas different from the first inert gas is used as the second inert gas, when the first inert gas is a nitrogen gas, for example, a hydrogen gas, a helium gas, or an argon gas is used as the second inert gas.

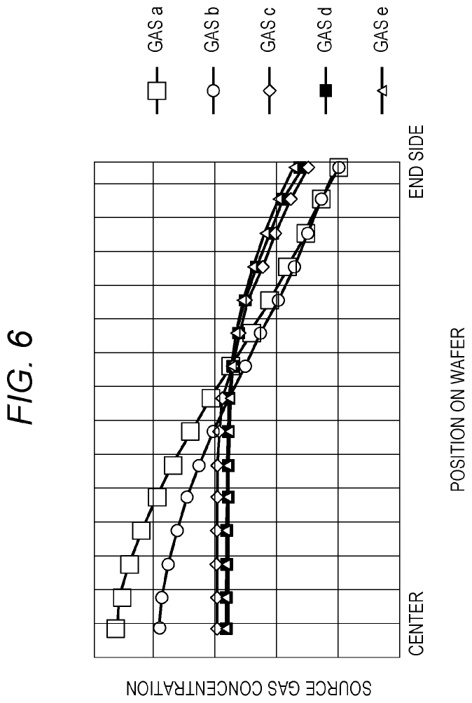

Here, FIG. 6 is a diagram illustrating the concentration of a source gas between a center and an end side of the wafer 200. This indicates how the concentration of the source gas, which is the process gas, depends on the type of the second inert gas. Note that a gas a has the smallest molecular weight, a gas b has a larger molecular weight, a gas c has a still larger molecular weight, and a gas e has the largest molecular weight. As illustrated in FIG. 6, the concentration of the source gas at the center of the wafer 200 tends to increase as the molecular weight of the second inert gas decreases. On the other hand, the concentration of the source gas on the end side of the wafer 200 is low regardless of the type of gas. Therefore, in the present embodiments, while the first inert gas, for example, N₂ is supplied to an end of the wafer 200 to suppress diffusion of the source gas, the film thickness uniformity on the wafer 200 is adjusted.

(4) Effects of Present Embodiments

In recent years, the amount of gas required has increased along with multilayering of wafers. When a gas is supplied from a side of a wafer, it is conceivable that a gas partial pressure on the wafer decreases as multilayering advances from a bare wafer. At this time, a difference in gas partial pressure between a center of the wafer and an edge thereof (referred to as within wafer: WiW) also tends to decrease, and it is conceivable that the amount of the gas supplied to the center of the wafer decreases. The decrease in the partial pressure can be controlled by extending processing time, but the WiW cannot be easily controlled because the WiW is determined by a wafer and a gas flow. According to the present embodiments, the WiW can also be easily controlled. As a result, a decrease in WiW in a multi-layered wafer can also be controlled.

Since the in-plane partial pressure of the wafer 200 can be controlled without increasing a flow rate of the process gas, an increase in a gas consumption amount can be suppressed.

### Other Embodiments

The present disclosure is not limited to the above-described embodiment, and various modifications can be made without departing from the gist of the present disclosure. For example, the first inert gas may be supplied not only to an end of the wafer 200 but also between the wafer 200 and the reaction tube 203, and for example, a plurality of tubes that supplies the first inert gas may be disposed.

In the above-described embodiments, the present disclosure can also be suitably applied to a case of forming any of a nitride film, an oxide film, a carbide film, and a borated film containing an element such as hafnium (Hf), tantalum (Ta), tungsten (W), cobalt (Co), yttrium (Y), ruthenium (Ru), aluminum (Al), titanium (Ti), zirconium (Zr), molybdenum (Mo), or silicon (Si), which are metal elements, or a composite film thereof.

In the case of forming a film containing any of the above-described elements, it is possible to use, as the source gas, a hafnium (Hf)-containing gas, a tantalum (Ta)-containing gas, a tungsten (W)-containing gas, a cobalt (Co)-containing gas, a yttrium (Y)-containing gas, a ruthenium (Ru)-containing gas, an aluminum (Al)-containing gas, a titanium (Ti)-containing gas, a zirconium (Zr)-containing gas, a molybdenum (Mo)-containing gas, a silicon (Si)-containing gas, or the like.

In addition, in the above-described embodiment, an example of using the N₂ gas as the first inert gas has been described, but the present disclosure is not limited thereto, and a rare gas such as an Ar gas, a He gas, a Ne gas, or a Xe gas may be used.

The above-described embodiment, modified examples, applications, and the like can be appropriately combined with each other and used. A processing condition at this time can be, for example, similar to that in the above-described embodiments.

It is preferable to individually prepare (prepare a plurality of) process recipes (programs in which a processing procedure, a processing condition, and the like are described) used for forming these various thin films according to the contents of substrate processing (film type, composition ratio, film quality, film thickness, processing procedure, processing condition, and the like of a thin film to be formed). Then, when substrate processing is started, it is preferable to appropriately select an appropriate process recipe from among a plurality of process recipes according to the contents of the substrate processing. Specifically, it is preferable to store (install) a plurality of process recipes individually prepared according to the contents of the substrate processing in advance in the memory included in the substrate processing apparatus via a telecommunication line or a recording medium (external memory) in which the process recipes are recorded. Then, when the substrate processing is started, the CPU included in the substrate processing apparatus preferably appropriately selects an appropriate process recipe from among the plurality of process recipes stored in the memory according to the contents of the substrate processing. With such a configuration, one substrate processing apparatus can generally form thin films of various film types, composition ratios, film qualities, and film thicknesses with good reproducibility. In addition, it is possible to reduce an operation load (for example, an input load of a processing procedure, a processing condition, and the like) of an operator, and it is possible to quickly start the substrate processing while avoiding an operation error.

The above-described process recipe is not limited to a newly created one, and can also be achieved, for example, by changing a process recipe of an existing substrate processing apparatus. When a process recipe is changed, the process recipe according to the present disclosure can be installed in an existing substrate processing apparatus via a telecommunication line or a recording medium in which the process recipe according to the present disclosure is recorded, or a process recipe itself of an existing substrate processing apparatus can be changed to the process recipe according to the present disclosure by operating an input/output device of the existing substrate processing apparatus.

In the above-described embodiments, an example has been described in which a film is formed using a process furnace having a structure in which a nozzle that supplies a process gas is erected in one reaction tube and an exhaust port is formed in a lower portion of the reaction tube in a substrate processing apparatus which is a batch type vertical apparatus that processes a plurality of substrates at a time, but the present disclosure can also be applied to a case of forming a film using a process furnace having another structure. For example, the present disclosure can also be applied to a case of forming a film using a process furnace having a structure in which a process gas flows from a nozzle having two reaction tubes (an outer reaction tube is referred to as an outer tube, and an inner reaction tube is referred to as an inner tube) having concentrical cross sections and erected in the inner tube to an exhaust port that is opened at a position on a side wall of the outer tube and facing the nozzle with the substrate interposed therebetween (line-symmetric position). The process gas may be supplied not from a nozzle erected in the inner tube but from a gas supply port opened on a side wall of the inner tube. At this time, the exhaust port opened on the outer tube may be opened according to a height at which a plurality of substrates stacked and housed in the process chamber is present. The shape of the exhaust port may be a hole shape or a slit shape.

In the above-described embodiment, an example has been described in which a film is formed using a substrate processing apparatus which is a batch type vertical apparatus that processes a plurality of substrates at a time, but the present disclosure is not limited thereto, and can be suitably applied to a case where a film is formed using a single wafer type substrate processing apparatus that processes one or several substrates at a time. In addition, in the above-described embodiments, an example has been described in which a thin film is formed using a substrate processing apparatus including a hot wall type processing furnace, but the present disclosure is not limited thereto, and can also be suitably applied to a case where a thin film is formed using a substrate processing apparatus including a cold wall type process furnace. Also in these cases, a processing condition can be, for example, similar to that in the above-described embodiment.

The present embodiment can be applied not only to a semiconductor manufacturing apparatus, but also to an apparatus that processes a glass substrate, such as an LCD apparatus. The film type is not particularly limited. For example, a metal compound (W, Ti, Hf, or the like), a silicon compound (SiN, Si, or the like), and the like are also applicable. The film forming processing includes, for example, CVD, PVD, processing of forming an oxide film or a nitride film, and processing of forming a metal-containing film.

The present disclosure makes it possible to process a large surface area wafer without increasing the supply amount and the discharge amount of a gas.

1. A method of manufacturing a semiconductor device, comprising:
loading a substrate into a process chamber in which the substrate is processed; and
processing the substrate by supplying a first inert gas to a peripheral portion of the substrate and simultaneously supplying a mixed gas of a second inert gas different from the first inert gas and a process gas to a surface of the substrate.

2. The method of claim 1, wherein the second inert gas is selected according to a processing condition.

3. The method of claim 1, wherein a concentration of the processing gas on the surface of the substrate is adjusted according to a type of the second inert gas.

4. The method of claim 1, wherein the second inert gas is constituted by a gas having a diffusion coefficient different from that of the first inert gas.

5. The method of claim 4, wherein the second inert gas comprises a gas having a diffusion coefficient larger than that of the first inert gas.

6. The method of claim 1, wherein the second inert gas has a molecular weight different from that of the first inert gas.

7. The method of claim 6, wherein the second inert gas has a molecular weight smaller than that of the first inert gas.

8. The method of claim 1, wherein a flow rate of the second inert gas is larger than that of the processing gas.

9. The method of claim 1, wherein a flow rate of the second inert gas is larger than that of the processing gas and that of the first inert gas.

10. The method of claim 1, wherein the second inert gas is selected according to a surface area of the substrate.

11. The method of claim 1, wherein the second inert gas is a rare gas.

12. The method of claim 11, wherein the second inert gas is at least one selected from the group consisting of a He gas, a Ne gas, an Ar gas, a Kr gas, and a Xe gas.

13. A substrate processing apparatus comprising:
an inert gas supply system disposed in a process chamber in which a substrate is processed and supplies a plurality of inert gases to the substrate in the process chamber;
a process gas supply system that supplies a process gas to the substrate in the process chamber; and
a controller configured to control the process gas supply system and the inert gas supply system so as to process the substrate by supplying a first inert gas among the plurality of inert gases to a peripheral portion of the substrate and simultaneously supplying a mixed gas of a second inert gas different from the first inert gas and the process gas to a surface of the substrate.

14. The substrate processing apparatus according to claim 13, wherein the inert gas supply system and the process gas supply system are disposed in the process chamber so as to be separated from each other in a circumferential direction of the substrate by a predetermined distance.

15. The substrate processing apparatus according to claim 13, wherein the inert gas supply system is disposed on each side of the process gas supply system.

16. A non-transitory computer-readable recording medium storing a program that causes, by a computer, a substrate processing apparatus to perform a process comprising:
loading a substrate into a process chamber; and
processing the substrate by supplying a first inert gas to a peripheral portion of the substrate and simultaneously supplying a mixed gas of a second inert gas different from the first inert gas and a process gas to a surface of the substrate.
